(19) United States
(12) Patent Application Publication
(10) Pub. No.: US 2026/0068502 A1
(43) Pub. Date: Mar. 5, 2026

(54) DISPLAY DEVICE

(71) Applicant: LG Display Co., Ltd., Seoul (KR)

(72) Inventors: Taehee Ko, Paju-si (KR); DongYoon Kim, Paju-si (KR); Dahye Kwon, Paju-si (KR)

(73) Assignee: LG Display Co., Ltd., Seoul (KR)

(21) Appl. No.: 19/280,547

(22) Filed: Jul. 25, 2025

(30) Foreign Application Priority Data
Aug. 27, 2024 (KR) 10-2024-0114907

(51) Int. Cl. H10K 59/80; H10K 59/35

(52) U.S. Cl. CPC H10K 59/876; H10K 59/353

(57) ABSTRACT

A display device includes a substrate, a first electrode disposed on the substrate and including an upper electrode and a lower electrode, a light emitting layer on the first electrode, and a second electrode on the light emitting layer, wherein the lower electrode includes a protruding part and a concave part disposed at a different height from the protruding part, and wherein the protruding part is spaced apart from the upper electrode.

### CROSS-REFERENCE TO RELATED APPLICATION

This application claims the benefit of priority of the Republic of Korea Patent Application No. 10-2024-0114907, filed on Aug. 27, 2024, which is hereby incorporated by reference in its entirety.

### BACKGROUND

### Field of Technology

The present disclosure relates to a display device.

### Discussion of the Related Art

As the information society develops, the demand for display devices for displaying images is increasing in various forms. Accordingly, various display devices such as liquid crystal display LCD, plasma display panel PDP, and organic light emitting display OLED are being utilized recently.

Among display devices, organic light emitting display devices are self-luminous, and have superior viewing angles and contrast ratios compared to liquid crystal display LCD, and do not require a separate backlight, making them lightweight and thin, and have the advantage of low power consumption. In addition, organic light emitting display devices may be driven by low direct current voltage, have a fast response speed, and have the advantage of low manufacturing costs.

An organic light emitting display device has a structure in which an organic light emitting element including a light emitting layer is disposed between a cathode that injects electrons and an anode that injects holes. An organic light emitting display device is a display device that utilizes the principle that when electrons generated from the cathode and holes generated from the anode are injected into the light emitting layer, the injected electrons and holes combine to generate excitons, and the generated excitons fall from an excited state to a ground state to emit light.

In order to solve the power consumption problem of the sub pixels of the display device, the light emission efficiency of each sub pixel is increased, and the problem of the user's visual perception being reduced may occur because light entering from the outside of the display device is reflected by wiring and electrodes inside the display device and is perceived by the user.

### SUMMARY

The present disclosure has been designed to solve the above-mentioned problems and aims to provide a display device that improves luminous efficiency to the outside and suppresses reflection of external light, thereby improving the user's visual experience.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, a display device includes a substrate, a first electrode disposed on the substrate and including an upper electrode and a lower electrode, a light emitting layer on the first electrode, and a second electrode on the light emitting layer, wherein the lower electrode includes a protruding part and a concave part disposed at a different height from the protruding part, and wherein the protruding part is spaced apart from the upper electrode.

In another aspect of the present disclosure, a display device includes a substrate including a first sub pixel, a first electrode including a first upper electrode and a first lower electrode, a first light emitting layer on the first electrode, and a second electrode on the first light emitting layer, wherein the first sub pixel disposed on the substrate, wherein the first lower electrode includes a first protruding part and a first concave part disposed at a different height from the first protruding part, and wherein the first protruding part is spaced apart from the first upper electrode.

Furthermore, the present disclosure provides a display device including a substrate; an upper electrode and a lower electrode disposed on the substrate; and an insulating layer disposed below the lower electrode, wherein the lower electrode comprises a protruding part, a concave part disposed at a height different from the protruding part, and an open part disposed in the protruding part and/or the concave part and exposing a portion of an upper surface of the insulating layer.

It is to be understood that both the foregoing general description and the following detailed description are by way of example and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the present disclosure.

FIG. 1 is a schematic perspective view of a display device according to an example embodiment of the present disclosure.

FIG. 2 is a plan view schematically showing a display device according to an example embodiment of the present disclosure.

FIG. 3 is a plan view of a display device according to an example embodiment of the present disclosure. In this case, FIG. 3 is an enlarged view of area A of FIG. 2.

FIG. 4 is a cross-sectional view of a display device according to an example embodiment of the present disclosure. In this case, FIG. 4 corresponds to cross-section along line I-I′ in FIG. 3.

FIG. 5 is a cross-sectional view of a display device according to an example embodiment of the present disclosure. In this case, FIG. 5 is an enlarged view of area B of FIG. 4.

FIG. 6 is a plan view schematically illustrating an upper electrode and a lower electrode according to an example embodiment of the present disclosure.

FIG. 7 is a cross-sectional view of a display device according to another example embodiment of the present disclosure. In this case, FIG. 7 corresponds to cross-section along line I-I′ in FIG. 3.

FIG. 8 is a plan view schematically illustrating an upper electrode and a lower electrode according to another example embodiment of the present disclosure.

FIG. 9 is a cross-sectional view of a display device according to an example embodiment of the present disclosure. In this case, FIG. 9 corresponds to cross-section along line II-II′ in FIG. 3.

FIG. 10A is a plan view of a display device according to another example embodiment of the present disclosure. In this case, FIG. 10A is an enlarged view of area A of FIG. 2.

FIG. 10B is an enlarged plan view of a display device according to another example embodiment of the present disclosure. In this case, FIG. 10B is an enlarged view of area C of FIG. 10A.

FIG. 11 is a cross-sectional view of a display device according to another example embodiment of the present disclosure. In this case, FIG. 11 corresponds to cross-section along line III-III′ in FIG. 10B.

### DETAILED DESCRIPTION

The advantages and features of the present disclosure, and the methods for achieving them, will become clear with reference to the example embodiments described in detail below together with the accompanying drawings. However, the present disclosure is not limited to the embodiments disclosed below but may be implemented in various different forms. These example embodiments are provided to make the present disclosure more complete and to more fully inform a person having ordinary skill in the art to which the present disclosure belongs of the scope of the disclosure. Further, the protected scope of the present disclosure may be defined by the claims and their equivalents.

The shapes, sizes, ratios, angles, numbers, etc., disclosed in the drawings for explaining example embodiments of the present disclosure are examples, and therefore the present disclosure is not limited to such details illustrated. Like reference numerals refer to like elements throughout the specification. In addition, in describing the present disclosure, where a detailed description of a related known technology may unnecessarily obscure the features of the present disclosure, such detailed description may be omitted. Where terms like “includes,” “has,” “consists of,” etc., are used in this specification, other parts may be added unless a more limiting term like “only” is used. Where a component is expressed in the singular, it includes a case where the plural is included, and vice versa, unless there is a specifically explicit description otherwise.

In interpreting a component, it should be interpreted as including the error range even if there is no separate explicit description.

Where a positional relationship is described, for example, where the positional relationship between two parts is described as ‘on ˜’, ‘upper ˜’, ‘lower ˜’, ‘next to ˜’, etc., one or more other parts may be located between the two parts, unless a more limiting term like ‘right’ or ‘directly’ is used.

Where a temporal relationship is described, for example, using phrases such as ‘after’, ‘following’, ‘next to’, or ‘before’, it can also include cases where there is no continuity, as long as a more limiting term like ‘right away’ or ‘directly’ is not used.

Although the terms first, second, etc., may be used to describe various components, these components are not limited by these terms. These terms are only used to refer one component separately from another. Accordingly, a first component referred to below may also be a second component, and vice versa, within the technical concept of the present disclosure.

The individual features of the various embodiments of the present disclosure may be partially or wholly combined with each other, and may be technically linked and driven in various ways. These example embodiments may be implemented independently of each other or may be implemented together in a connected or associated relationship.

Hereinafter, example embodiments of the present disclosure will be described in detail with reference to the drawings.

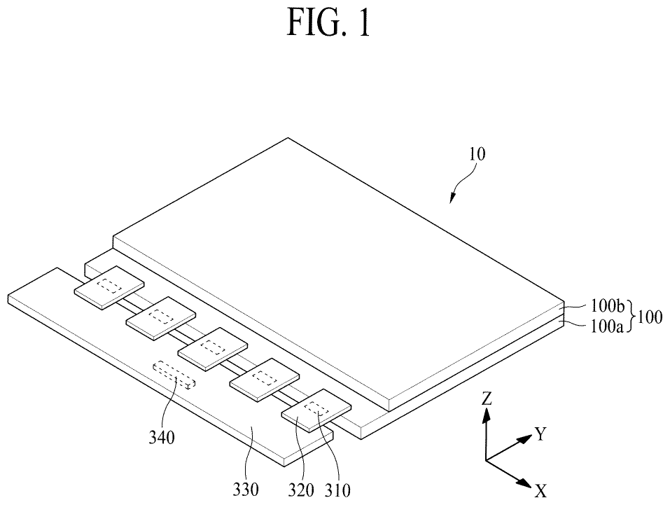

FIG. 1 is a schematic perspective view of a display device according to an example embodiment of the present disclosure.

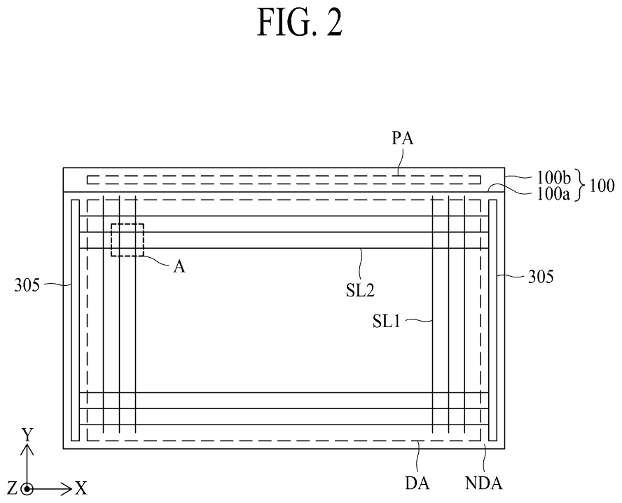

FIG. 2 is a plan view schematically showing a display device according to an example embodiment of the present disclosure.

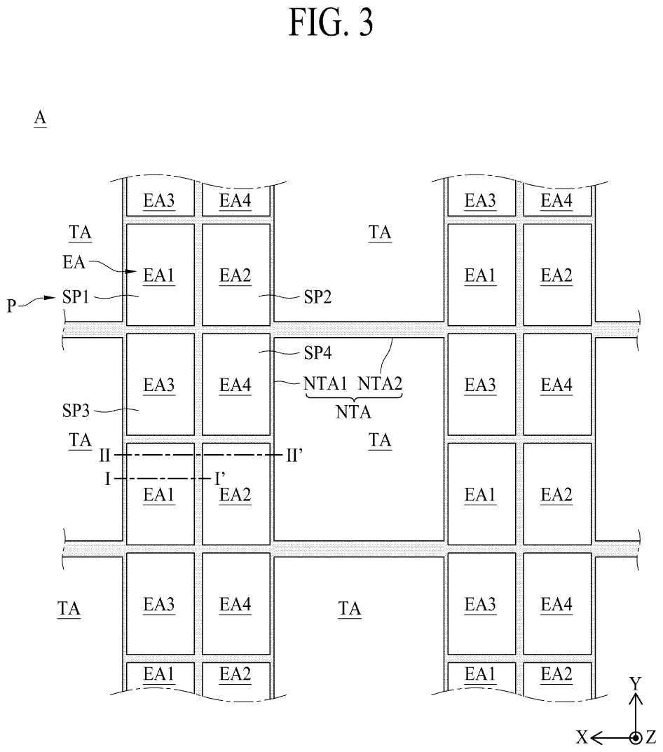

FIG. 3 is a plan view of a display device according to an example embodiment of the present disclosure. In this case, FIG. 3 is an enlarged view of area A of FIG. 2.

FIG. 1 is a perspective view schematically showing a display device according to an example embodiment of the present disclosure, and FIG. 2 is a plan view schematically showing a display device according to an example embodiment of the present disclosure.

Hereinafter, the X-axis represents a direction parallel to the scan line, the Y-axis represents a direction parallel to the data line, and the Z-axis represents the height direction of the display device 10.

The display device 10 according to one embodiment of the present disclosure has been described mainly as being implemented as an organic light emitting display, but may also be implemented as a liquid crystal display, a plasma display panel PDP, a quantum dot light emitting display QLED, or an electrophoresis display.

As shown in FIGS. 1 and 2, a display device 10 according to an example embodiment of the present disclosure includes a display panel 100, a source drive integrated circuit hereinafter referred to as “IC” 310, a flexible film 320, a circuit board 330, and a timing control unit 340.

The display panel 100 includes the first substrate 100a and the second substrate 100b facing each other. The second substrate 100b may be a sealing substrate. The first substrate 100a may be a plastic film, a glass substrate, or a silicon wafer substrate formed using a semiconductor process. The second substrate 100b may be a plastic film, a glass substrate, or a sealing film. The first substrate 100a and the second substrate 100b may be made of a transparent material.

The display panel 100 may be divided into a display area DA where pixels are formed to display an image and a non-display area NDA where no image is displayed.

The display area DA may be disposed with first signal lines SL1, second signal lines SL2 and pixels, and the non-display area NDA may be disposed with a pad area PA in which pads are disposed and at least one scan driver 305.

The first signal lines SL1 may extend in a first direction, the Y-axis direction, and may intersect with the second signal lines SL2 in the display area DA. The second signal lines SL2 may extend in a second direction, the X-axis direction, in the display area DA. The pixels are disposed in an area where the first signal line SL1 is provided or an area where the first signal line SL1 and the second signal line SL2 intersect, and emit a predetermined amount of light to display an image.

The source drive IC 310 receives digital video data and a source control signal from the timing control unit 340. The source drive IC 310 converts digital video data into analog data voltages according to the source control signal and supplies the same to data lines. When the source drive IC 310 is manufactured as a driving chip, it may be mounted on the flexible film 320 in a COF (chip on film) or COP (chip on plastic) manner.

The wires connecting the pads and the source drive IC 310, and the wires connecting the pads and the wires of the circuit board 330 may be disposed on the flexible film 320. The flexible film 320 is attached onto the pads using an anisotropic conducting film, thereby connecting the pads and the wires of the flexible film 320.

The circuit board 330 may be attached to the flexible films 320. The circuit board 330 may have a plurality of circuits implemented with driving chips mounted thereon. For example, the timing control unit 340 may be mounted on the circuit board 330. The circuit board 330 may be a printed circuit board or a flexible printed circuit board.

The timing control unit 340 receives digital video data and a timing signal from an external system board not shown. The timing control unit 340 generates a gate control signal for controlling the operation timing of the scan driving unit based on the timing signal and a source control signal for controlling the source drive ICs 310. The timing control unit 340 supplies the gate control signal to the scan driving unit 305 and the source control signal to the source drive ICs 310.

FIG. 3 is a plan view of a display device according to an example embodiment of the present disclosure. In this case, FIG. 3 is an enlarged view of area A of FIG. 2.

As may be seen in FIG. 3, a display device according to an example embodiment of the present disclosure comprises a plurality of pixel areas P, a non-transparent area NTA, and a plurality of transmissive areas TA.

The plurality of transparent areas TA are areas that allow most of the light incident from the outside to pass through, and the above-described non-transparent area NTA and the above-described plurality of pixel areas P are areas that do not allow most of the light incident from the outside to pass through. In this case, the light transmittance in the above-described plurality of transparent areas TA may be higher than the light transmittance in the above-described non-transparent area NTA and the above-described plurality of pixel areas P. Since the display panel 100 is formed by including the above-described plurality of transparent areas TA, an object or background located on the back surface of the display panel (see 100 of FIG. 1) may be recognized.

The plurality of transmission areas TA may be disposed in a first direction, for example, the Y direction, and spaced apart in a second direction, for example, the X direction, and disposed in the first direction.

The area of each of the transmission areas TA may be formed to be larger than the area of any one of the sub pixels SP1, SP2, SP3, SP4 disposed in each of the mentioned pixel areas P.

The plurality of pixel areas P may be disposed between the plurality of transparent areas TA. The plurality of pixel areas P may be disposed between the plurality of transparent areas TA and may emit light.

Each of the plurality of pixel areas P may include the first sub pixel SP1 to the fourth sub pixel SP4 in which light emitting elements are disposed to emit light.

The first sub pixel SP1 emits light of a first color, the second sub pixel SP2 emits light of a second color, the third sub pixel SP3 emits light of a third color, and the fourth sub pixel SP4 emits light of a fourth color. The first to fourth sub pixels SP1 to SP4 may each emit light of a different color. For example, the first sub pixel SP1 may emit red, the second sub pixel SP2 may emit white, the third sub pixel SP3 may emit green, and the fourth sub pixel SP4 may emit blue. Meanwhile, the present disclosure is not limited thereto, and the color of light emitted by each of the sub pixels SP1, SP2, SP3, and SP4 and the arrangement order of the sub pixels SP1, SP2, SP3, and SP4 may be variously changed.

The non-transparent region NTA may include a first non-transparent region NTA1 and a second non-transparent region NTA2.

The first non-transparent area NTA1 may extend in a first direction, in the Y-axis direction, from the display area (see DA of FIG. 2). In the display panel (see 100 of FIG. 2), a plurality of the first non-transparent areas NTA1 may be disposed to be spaced apart from each other, and one of the plurality of transparent areas TA may be disposed between two adjacent first non-transparent areas NTA1. In the first non-transparent areas NTA1, first signal lines (see SL1 of FIG. 2) extending in the first direction, in the Y-axis direction, may be disposed to be spaced apart from each other.

The first signal lines (see SL1 in FIG. 2) may include, for example, at least one of a common power line, a reference line, data lines, and a pixel power line.

The pixel power line may supply first power to the driving thin film transistor of each of the sub pixels SP1, SP2, SP3, SP4 disposed in the plurality of pixel areas P. The common power line may supply second power to the cathode electrodes of the sub pixels SP1, SP2, SP3, SP4 disposed in the plurality of pixel areas P. At this time, the second power may be a common power supplied commonly to the sub pixels SP1, SP2, SP3, SP4.

The reference line may supply an initialization voltage or a reference voltage to each of the driving thin film transistors of the sub pixels SP1, SP2, SP3, SP4 disposed in the plurality of pixel areas P. Each of the data lines may supply a data voltage to the sub pixels SP1, SP2, SP3, SP4.

The second non-transparent area NTA2 may extend in a second direction, in the X-axis direction, from the display area (see DA of FIG. 2). In the display panel (see 100 of FIG. 2), a plurality of second non-transparent areas NTA2 are spaced apart from each other, and one of the plurality of transparent areas TA may be disposed between two adjacent second non-transparent areas NTA2. A second signal line SL2 may be disposed in the second non-transparent area NTA2.

The second signal line SL2 extends in a second direction, in the X-axis direction, and may include, for example, a scan line SCANL. The scan line SCANL may supply a scan signal to the sub pixels SP1, SP2, SP3, SP4 disposed in the plurality of pixel areas P.

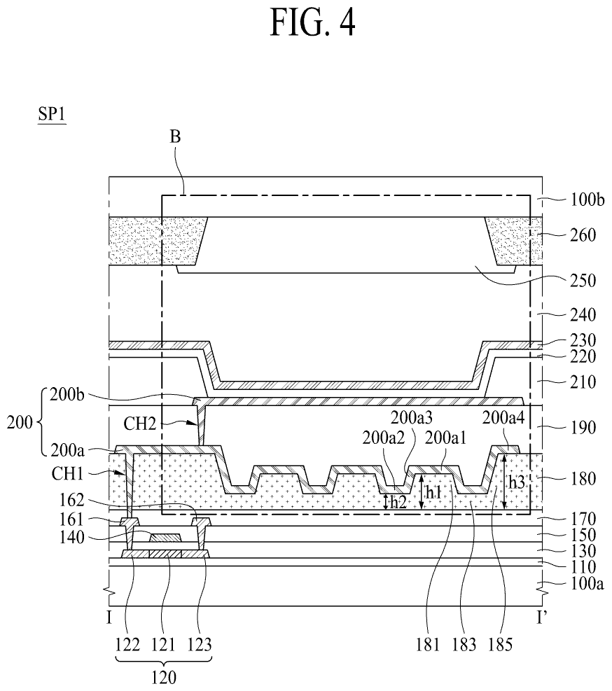

FIG. 4 is a cross-sectional view of a display device according to an example embodiment of the present disclosure. In this case, FIG. 4 corresponds to cross-section along line I-I′ in FIG. 3.

As may be seen in FIG. 4, a display device according to an example embodiment of the present disclosure includes a first substrate 100a, a buffer layer 110, an active layer 120, a gate insulating layer 130, a gate electrode 140, an interlayer insulating layer 150, a source electrode 161, a drain electrode 162, a first insulating layer 170, a second insulating layer 180, a lower electrode 200a of the first electrode 200, a planarization layer 190, an upper electrode 200b of the first electrode 200, a bank 210, a light emitting layer 220, a second electrode 230, an encapsulation layer 240, a color filter 250, a black matrix 260, and a second substrate 100b.

The first substrate 100a may be made of glass or plastic. In particular, the first substrate 100a may be made of a transparent plastic having flexible properties, for example, polyimide. When polyimide is used as the first substrate 100a, a heat-resistant polyimide capable of withstanding high temperatures may be used, in consideration of the fact that a high-temperature deposition process is performed on the first substrate 100a.

The buffer layer 110 may be disposed on the first substrate 100a. The buffer layer 110 may block air and moisture to protect the active layer 120. The buffer layer 110 may be formed of an inorganic insulating material such as silicon oxide, silicon nitride, or metal oxide, but is not necessarily limited thereto and may be formed of an organic insulating material.

Meanwhile, although not specifically illustrated, a light blocking layer may be formed between the first substrate 100a and the buffer layer 110. In this case, the light blocking layer may prevent or block light entering from the lower end of the first substrate 100a from reaching the active layer 120.

The active layer 120 may be disposed on the buffer layer 110. The active layer 120 may be formed of a semiconductor material, for example, one of amorphous silicon (a-Si), polycrystalline silicon (Poly Si), and oxide semiconductor (Oxide) materials.

The active layer 120 includes a channel part 121, a first connection part 122 disposed on one side of the channel part 121, for example, on the left side, and a second connection part 123 disposed on the other side of the channel part 121, for example, on the right side.

The channel part 121 overlaps with the gate electrode 140. By being formed in this manner, in the conductorized process of conductorization the active layer 120, the channel part 121 is protected by the gate electrode 140 and is not conductorized, thereby maintaining semiconductor characteristics.

The first connection part 122 and the second connection part 123 may be disposed with conductorized property, for example, by a conductorized process of performing plasma treatment on a semiconductor material or doping with ions using the gate electrode 140 as a mask. The first connection part 122 and the second connection part 123 formed by the conductorized process have excellent conductorized property and may thus serve as electrodes or wiring.

The gate insulating layer 130 may be disposed on the active layer 120. The gate insulating layer 130 may be disposed on the entire surface of the first substrate 100a, but is not limited thereto. A portion of the gate insulating layer 130 may be patterned so that one end and the other end of the gate insulating layer 130 correspond to one end and the other end of the gate electrode 140, respectively.

The gate insulating layer 130 may include, but is not limited to, a silicon nitride film (SiNx) or a silicon oxide film (SiOx). The gate insulating layer 130 may be formed of a single layer or multiple layers including an inorganic insulating material and/or an organic insulating material.

The gate electrode 140 may be disposed on the gate insulating layer 130.

The gate electrode 140 may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode 140 may have a structure including one metal layer or a multilayer film structure including at least two metal layers each having different physical properties.

The interlayer insulating layer 150 may be disposed on the gate electrode 140. The interlayer insulating layer 150 insulates between the gate electrode 140 and the source electrode 161, and further insulates between the gate electrode 140 and the drain electrode 162. The interlayer insulating layer 150 may be formed of a single layer or multiple layers including an inorganic insulating material and/or an organic insulating material.

A contact hole may be formed in the interlayer insulating layer 150. Accordingly, a portion of the upper surface of the first connection part 122 of the active layer 120 may be exposed by one contact hole, and further, a part of the upper surface of the second connection part 123 of the active layer 120 may be exposed by another contact hole.

The source electrode 161 and the drain electrode 162 may be disposed on the interlayer insulating layer 150.

The source electrode 161 may be electrically connected to the first connection part 122 of the active layer 120 by a contact hole, and the drain electrode 162 may be electrically connected to the second connection part 123 of the active layer 120 by a contact hole.

The source electrode 161 and the drain electrode 162 may be formed of the same material as the gate electrode 140, but are not limited thereto and may be formed of a material according to knowledge in the art.

The first insulating layer 170 is disposed on the source electrode 161, the drain electrode 162, and the interlayer insulating layer 150. The first insulating layer 170 may be formed of a single layer or multiple layers including an inorganic insulating material and/or an organic insulating material.

The second insulating layer 180 is disposed on the first insulating layer 170.

The second insulating layer 180 may be formed of a single layer or multiple layers including an inorganic insulating material and/or an organic insulating material.

According to one embodiment of the present disclosure, the second insulating layer 180 may be formed including portions having different heights. The second insulating layer 180 may be formed including a first part 181 having a first height h1, a second part 183 having a second height h2, and a third part 185 having a third height h3. In this case, the first height h1, the second height h2, and the third height h3 may be different heights, for example, the third height h3 may be greater than the first height h1 and the second height h2, and the first height h1 may be greater than the second height h2. The second insulating layer 180 may be pattern-formed by a multi-tone mask. In this case, the first part 181, the second part 183, and the third part 185 may be formed in the same process by the multi-tone mask. In this case, the multi-tone mask may be defined as a mask that includes areas having different transmittances within one mask. Therefore, when the second insulating layer 180 is pattern-formed using the multi-tone mask, the second insulating layer 180 may be pattern-formed at different heights while passing through areas having different transmittances.

The first part 181 and the second part 183 may overlap with the light emitting area defined by the bank 210. Therefore, the first part 181 and the second part 183 may overlap with the upper electrode 200b of the first electrode 200 that is exposed and not covered by the bank 210.

According to one embodiment of the present disclosure, by adjusting the first height h1 and the second height h2 of each of the first part 181 and the second part 183, the distance between the lower electrode 200a and the second electrode 230 may be adjusted to become an integer multiple of a half wavelength of any one of red R, green G, and blue B light.

The first part 181 and the second part 183 may be configured to have various heights depending on the color of light that the first sub pixel SP1 intends to display.

The third part 185 may not overlap with the light emitting region. A first contact hole CH1 may be formed in the third part 185. The upper surface of the source electrode 161 may be exposed by the first contact hole CH1.

The first electrode 200 may be disposed on the second insulating layer 180. The first electrode 200 may function as an anode. Accordingly, when a signal is applied to the first electrode 200, holes moving from the first electrode 200 may flow into the light emitting layer 220.

The first electrode 200 includes a lower electrode 200a and an upper electrode 200b. In this case, the lower electrode 200a and the upper electrode 200b are formed to be spaced apart from each other. In detail, for example, a planarization layer 190 is disposed between the lower electrode 200a and the upper electrode 200b so that the lower electrode 200a and the upper electrode 200b may be spaced apart from each other.

Meanwhile, by adjusting the distance between the lower electrode 200a and the upper electrode 200b, the degree of reflection of external light introduced from the outside of the display device may be reduced. In detail, the distance between the lower electrode 200a and the upper electrode 200b may be adjusted such that light introduced from outside the second substrate 100b and reflected by the lower electrode 200a and light introduced from outside the second substrate 100b and reflected by the upper electrode 200b cause destructive interference with each other. For example, by adjusting the distance between the protruding part 200a1 of the lower electrode 200a and the upper electrode 200b or the distance between the concave part 200a2 of the lower electrode 200a and the upper electrode 200b, the external light reflected from the protruding part 200a1 or the concave part 200a2 and the external light reflected from the upper electrode 200b cause destructive interference with each other, thereby reducing the degree of external light reflection. In this case, the user may secure improved visibility due to the reduction in external light reflection. For example, the distance between the protruding part 200a1 or the concave part 200a and the upper electrode 200b may be the distance between the protruding part 200a1 or the concave part 200a and the upper electrode 200b in the height direction of the display device 10 (Z-axis).

The lower electrode 200a is disposed on the second insulating layer 180. The lower electrode 200a may be a reflective electrode. The lower electrode 200a may be formed of a material having high reflectivity. The lower electrode 200a may be formed of, for example, a plurality of layers in which aluminum palladium copper (APC), aluminum (Al), and indium tin oxide (ITO) are alternately laminated, a double layer structure of Ag/ITO, a double layer structure of APC/ITO, a triple layer structure of ITO/Ag/ITO, or a triple layer structure of ITO/APC/ITO, but is not limited thereto, and may be formed of a single metal layer having high reflectivity or a plurality of metal layers.

According to one embodiment of the present disclosure, the lower electrode 200a may be formed in a curved structure. In detail, the lower electrode 200a may be disposed on the second insulating layer 180 and may be formed in the same shape as the shapes of the first part 181, the second part 183, and the third part 185 of the second insulating layer 180. Accordingly, one portion of the lower electrode 200a may be disposed on the first part 181 and formed in a protruding structure, and the other portion of the lower electrode 200a may be disposed on the second part 183 and formed in a concave structure. By forming in this manner, light that has traveled from the light emitting layer 220 toward the lower electrode 200a may be emitted to the outside of the first sub pixel SP1 without being trapped inside, thereby increasing light emission efficiency.

The lower electrode 200a may include a protruding part 200a1, a concave part 200a2, an inclined part 200a3, and a contact part 200a4. The protruding part 200a1, the concave part 200a2, the inclined part 200a3, and the contact part 200a4 may be provided continuously with each other.

The protruding part 200a1 is disposed on the first part 181 of the second insulating layer 180, and the concave part 200a2 is disposed on the second part 183 of the second insulating layer 180. Therefore, the protruding part 200a1 may be disposed at a higher position than the concave part 200a2.

The inclined part 200a3 may be disposed between the protruding part 200a1 and the mentioned concave part 200a2. The inclined part 200a3 may be provided so as to be inclined at a predetermined angle from the upper surfaces of the protruding part 200a1 and the concave part 200a2. According to one embodiment of the present disclosure, since the light emitted from the light emitting layer 220 is reflected by the inclined part 200a3, the amount of light emitted to the outside of the first sub pixel SP1 may increase.

The contact part 200a4 is disposed on the third part 185 of the second insulating layer 180. The contact part 200a4 may be electrically connected to the source electrode 161 through the first contact hole CH1 formed in the third part 185 of the second insulating layer 180, and may be electrically connected to the upper electrode 200b through the second contact hole CH2.

The planarization layer 190 may be disposed on the second insulating layer 180 and the lower electrode 200a of the first electrode 200. The planarization layer 190 may be disposed on the second insulating layer 180 and the lower electrode 200a of the first electrode 200 so that the upper surface of the planarization layer 190 may be planarized.

The above planarization layer 190 is disposed with the second contact hole CH2, and a portion of the upper surface of the lower electrode 200a may be exposed by the second contact hole CH2.

The planarization layer 190 may be composed of an organic insulating layer material. The planarization layer 190 may be composed of an organic insulating material such as, for example, an acrylic resin, an epoxy resin, a phenolic resin, a polyamide resin, or a polyimide resin.

The upper electrode 200b of the first electrode 200 may be disposed on the planarization layer 190. The upper electrode 200b may be electrically connected to the lower electrode 200a through the second contact hole CH2.

The upper electrode 200b may be formed as a transparent electrode. The upper electrode 200b may be formed of, for example, indium tin oxide (ITO) or indium zinc oxide (IZO).

The upper electrode 200b is disposed on the planarization layer 190, and thus may be formed in a different shape from the lower electrode 200a. In detail, unlike the lower electrode 200a which is formed in a curved shape, the upper electrode 200b may be formed to be flat. Accordingly, the upper surface of the upper electrode 200b may be formed flat without having a separate protruding part and/or concave part.

According to one embodiment of the present disclosure, since the upper surface of the upper electrode 200b is formed to be flat, light may be uniformly formed in each region of the light emitting layer 220 in contact with the upper electrode 200b. If the upper surface of the upper electrode 200b is not formed in a flat shape, the light emitting layer 220 may not be uniformly formed due to the surface of the upper electrode being curved or protruding during the process of forming the light emitting layer 220. In this case, light emitted from the light emitting layer 220 that is not uniformly formed may have a certain deviation, and thus may not form uniform light.

The bank 210 may be disposed on the first electrode 200. In this case, a portion of the upper surface of the first electrode 200 that is exposed and not covered by the bank 210 becomes a light emitting area.

The bank 210 may be formed of an organic film such as an acrylic resin, an epoxy resin, a phenolic resin, a polyamide resin, or a polyimide resin.

The light emitting layer 220 may be disposed on the first electrode 200. The light emitting layer 220 may include red, green, and blue light emitting layers patterned for each sub pixel, or may be formed of a white light emitting layer connected to all pixels. When the light emitting layer 220 is formed of a white light emitting layer, the light emitting layer 220 may include, for example, a first stack including a blue light emitting layer, for example, a second stack including a yellow-green light emitting layer, and a charge generation layer disposed between the first stack and the second stack, but is not necessarily limited thereto.

According to one embodiment of the present disclosure, the light emitting layer 220 disposed in the first sub pixel SP1 may emit, for example, white light.

The second electrode 230 may be disposed on the light emitting layer 220. The second electrode 230 may function as a cathode.

The sealing layer 240 may be disposed on the second electrode 230. The sealing layer 240 may be disposed on the entire surface of the first substrate 100a.

The sealing layer 240 may be formed of acrylic resin, epoxy resin, polyimide, polyethylene (PE), or silicon oxycarbon (SiOC).

Meanwhile, although not specifically illustrated, the sealing layer 240 may include a first sealing layer including an inorganic substance, a second sealing layer including an organic substance, and a third sealing layer including an inorganic substance.

The color filter 250 may be disposed on the sealing layer 240. In detail, the color filter 250 may be formed to correspond to the first sub pixel SP1.

The color filter 250 may transmit light of any one color among red, green, and blue. Accordingly, light emitted from the light emitting layer 220 disposed in the first sub pixel SP1 passes through the color filter 250 and is emitted to the outside. In this case, when the light emitted from the light emitting layer 220 is white and the color filter 250 is a red color filter that transmits red light, red light may be emitted from the first sub pixel SP1. However, the present disclosure is not limited thereto, and light of various colors may be emitted from the first sub pixel SP1 depending on the combination of the light emitting layer 220 and the color filter 250 disposed in the first sub pixel SP1. As another example, when the color filter 250 is a green color filter that transmits green light, green light may be emitted from the first sub pixel SP1, and as another example, when the color filter 250 is a blue color filter that transmits blue light, blue light may be emitted from the first sub pixel SP1.

The black matrix 260 may be disposed on the sealing layer 240 and the color filter 250.

The black matrix 260 overlaps with the bank 210 and is formed between the first sub pixel SP1 and the adjacent other sub pixels (see the second sub pixel SP2 to the fourth sub pixel SP4 of FIG. 3), thereby preventing or suppressing the problem of light emitted from the first sub pixel SP1 and the other sub pixels (see the second sub pixel SP2 to the fourth sub pixel SP4 of FIG. 3) being mixed with each other and causing color mixing.

The second substrate 100b may be disposed on the black matrix 260. The second substrate 100b may be joined to the first substrate 100a while facing it.

The second substrate 100b may be made of glass or plastic. In particular, the second substrate 100b may be made of a transparent plastic having flexible property, for example, polyimide.

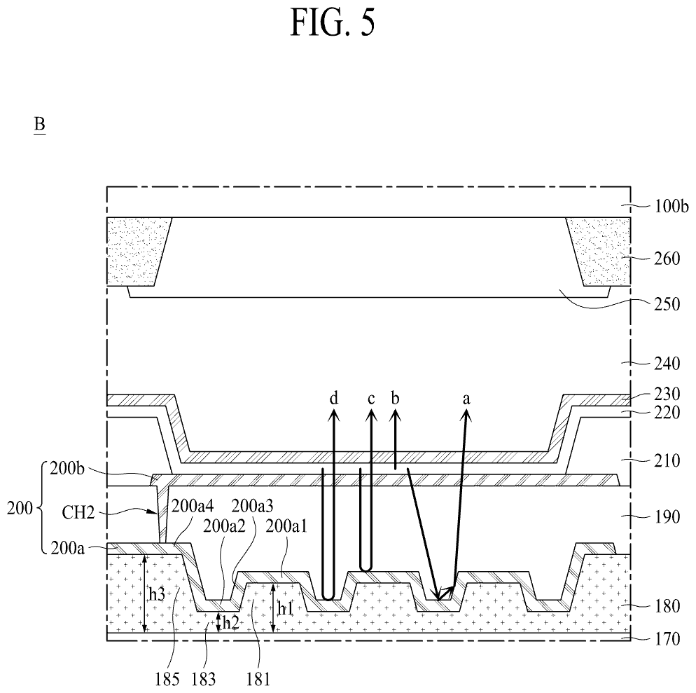

FIG. 5 is a cross-sectional view of a display device according to an example embodiment of the present disclosure. In this case, FIG. 5 is an enlarged view of area B of FIG. 4, and FIG. 5 relates to the same embodiment as the embodiment of FIG. 4, and the same components are given the same numbers, and repeated descriptions are omitted.

According to an example embodiment of the present disclosure, the second insulating layer 180 includes a first part 181 and a second part 183 having different heights. Accordingly, the lower electrode 200a of the first electrode 200 disposed on the second insulating layer 180 may be disposed with the same curved shape along the curved shape of the second insulating layer 180.

In this case, the protruding part 200a1 of the lower electrode 200a disposed on the first part 181 and the concave part 200a2 of the lower electrode 200a disposed on the second part 183 may be formed at different positions or heights.

Accordingly, the distances in each region of the second electrode 230 and the lower electrode 200a may be formed differently by the curved shape of the lower electrode 200a. In detail, the shortest distance between the protruding part 200a1 of the lower electrode 200a and the second electrode 230 may be different from the shortest distance between the concave part 200a2 of the lower electrode 200a and the second electrode 230.

According to an example embodiment of the present disclosure, the shortest distance between the protruding part 200a1 and the second electrode 230 and the shortest distance between the concave part 200a2 and the second electrode 230 may be provided differently depending on the color of light to be displayed in the first sub pixel SP1. For example, when the first sub pixel SP1 displays red R light, the shortest distance between the protruding part 200a1 and the second electrode 230 and the shortest distance between the concave part 200a2 and the second electrode 230 may be formed as distances that are integer multiples of half a wavelength of light displaying red R, respectively. By forming in this manner, a microcavity (or micro-resonance) is formed for the red R light, so that the light emission efficiency of the red R light emitted through the first sub pixel SP1 may be increased.

Meanwhile, and not limited thereto, as another example, when the first sub pixel SP1 displays green G light, the shortest distance between the protruding part 200a1 and the second electrode 230 and the shortest distance between the concave part 200a2 and the second electrode 230 may be formed as distances that are integer multiples of half a wavelength of the light displaying green G, respectively. By forming in this manner, a microcavity (or micro-resonance) is formed for the green G light, so that the light emission efficiency of the green G light emitted through the first sub pixel SP1 may be increased.

As another example, when the first sub pixel SP1 displays blue B light, the shortest distance between the protruding part 200a1 and the second electrode 230 and the shortest distance between the concave part 200a2 and the second electrode 230 may be formed as distances that are integer multiples of half a wavelength of the light displaying blue B, respectively. By forming in this manner, a microcavity (or micro-resonance) is formed for the blue B light, so that the light emission efficiency of the blue B light emitted through the first sub pixel SP1 may be increased.

The light b emitted from the light emitting layer 220 is emitted in the direction of the second substrate 100b. In this case, the light b may implement the color that the first sub pixel SP1 wants to display by passing through the color filter 250.

Other light c emitted from the light emitting layer 220 may pass through the upper electrode 200b and be reflected from the protruding part 200a1 of the lower electrode 200a. According to one embodiment of the present disclosure, since the protruding part 200a1 is disposed at a position where the distance between the protruding part 200a1 and the second electrode 230 is an integer multiple of a half wavelength of one of the red R, green G and blue B lights, the light b emitted from the light emitting layer 220 and the light c reflected from the protruding part 200a1 may constructively interfere with each other to form a micro cavity. For example, the distance between the protruding part 200a1 and the second electrode 230 may be the distance between the protruding part 200a1 and the second electrode 230 in the height direction of the display device 10 (Z-axis).

Similarly, another light d emitted from the light emitting layer 220 may pass through the upper electrode 200b and be reflected from the concave part 200a2 of the lower electrode 200a. According to one embodiment of the present disclosure, since the concave part 200a2 is disposed at a position where the distance between the concave part 200a2 and the second electrode 230 is an integer multiple of a half wavelength of one of the red R, green G, and blue B lights, the light b emitted from the light emitting layer 220 and the light d reflected from the concave part 200a2 can form a micro cavity by forming a reinforcing line between each other. For example, the distance between the concave part 200a2 and the second electrode 230 may be the distance between the concave part 200a2 and the second electrode 230 in the height direction of the display device 10 (Z-axis).

Therefore, according to one embodiment of the present disclosure, light a emitted from the light emitting layer 220 and forming a predetermined angle with the upper surface of the light emitting layer 220 may pass through the upper electrode 200b and be reflected by the inclined part 200a3 of the lower electrode 200a. In this case, since the inclined part 200a3 is formed to be inclined at a predetermined angle with the upper surface of the light emitting layer 220, the light a may be reflected by the inclined part 200a3 so as to pass through the light emitting layer 220 and toward the color filter 250. Accordingly, the ratio of the light a reflected by the inclined part 200a3 and emitted outside the first sub pixel SP1 increases, thereby increasing the light emission efficiency of the first sub pixel SP1.

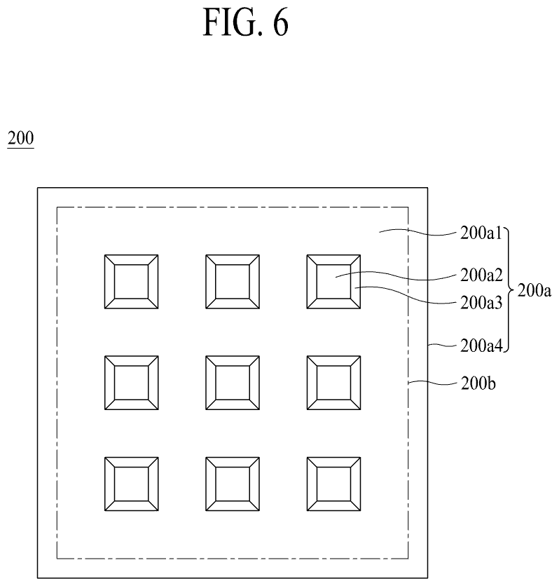

FIG. 6 is a plan view schematically illustrating an upper electrode and a lower electrode according to an example embodiment of the present disclosure. Meanwhile, the embodiment of FIG. 6 is the same as the embodiment of FIG. 4, and the same reference numerals are given to the same components, and repeated descriptions are omitted.

As may be seen in FIG. 6, the first electrode 200 is composed of a lower electrode 200a and an upper electrode 200b.

The lower electrode 200a is composed of a protruding part 200a1, a concave part 200a2, an inclined part 200a3, and a contact part 200a4.

According to one embodiment of the present disclosure, the concave parts 200a2 may be formed in multiple numbers between the protruding parts 200a1. For example, the concave parts 200a2 may be disposed in three horizontal directions and three vertical directions. However, the present disclosure is not limited thereto, and may be disposed in various numbers according to the level of a person skilled in the art.

The inclined part 200a3 may be provided to surround the periphery of the concave part 200a2.

According to an example embodiment of the present disclosure, by positioning the protruding part 200a1 and the concave part 200a2 at a distance that forms a micro cavity for light of one color emitted from the light emitting layer (see 220 of FIG. 4), the light emitting efficiency of the first sub pixel (see SP1 of FIG. 4) may be improved.

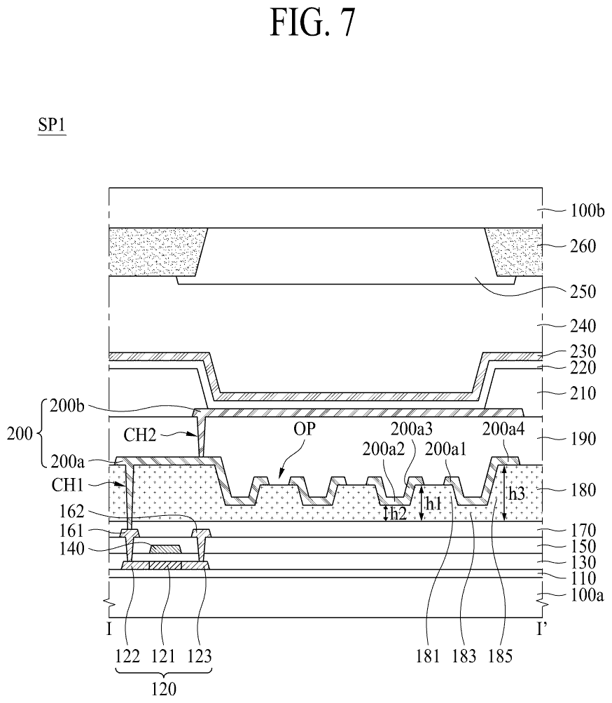

FIG. 7 is a cross-sectional view of a display device according to another example embodiment of the present disclosure. In this case, FIG. 7 corresponds to cross-section along line I-I′ in FIG. 3. Meanwhile, the embodiment of FIG. 7 is identical to the embodiment of FIG. 5 except for the configuration of the open part, so the following description will focus on the different configuration.

As may be seen in FIG. 7, a display device according to another example embodiment of the present disclosure includes a first substrate 100a, a buffer layer 110, an active layer 120, a gate insulating layer 130, a gate electrode 140, an interlayer insulating layer 150, a source electrode 161, a drain electrode 162, a first insulating layer 170, a second insulating layer 180, a lower electrode 200a of the first electrode 200, a planarization layer 190, an upper electrode 200b of the first electrode 200, a bank 210, a light emitting layer 220, a second electrode 230, an encapsulation layer 240, a color filter 250, a black matrix 260, and a second substrate 100b.

According to another example embodiment of the present disclosure, the lower electrode 200a may include an open part OP that exposes a portion of the upper surface of the second insulating layer 180.

The open part OP may be formed, for example, in one of the protruding part 200a1 and the concave part 200a2 of the lower electrode 200a. Since the open part OP is formed in one of the protruding part 200a1 and the concave part 200a2, the inclined part 200a3 may not expose the upper surface of the second insulating layer 180. Accordingly, light emitted from the light emitting layer 220 while forming a predetermined angle with the upper surface of the light emitting layer 220 may be reflected by the inclined part 200a3, thereby improving the light emitting efficiency of the first sub pixel SP1.

Meanwhile, in FIG. 7, the open part OP is formed in the area where the protruding part 200a1 is formed to expose a portion of the upper surface of the first part 181 of the second insulating layer 180, but it is not limited thereto. The open part OP may be formed in the area where the concave part 200a2 is formed to expose a portion of the upper surface of the second part 183 of the second insulating layer 180, and the open part OP may be formed in the area where the protruding part 200a1 and the concave part 200a2 are formed to expose a portion of the upper surfaces of the first part 181 and the second part 183 of the second insulating layer 180.

According to another example embodiment of the present disclosure, by forming the open part OP in a portion of the lower electrode 200a, the degree to which external light introduced from outside the display device of the present disclosure through the second substrate 100b is reflected and recognized by the user may be reduced or eliminated. By forming in this manner, the visual sensation of the user viewing the display device may be improved.

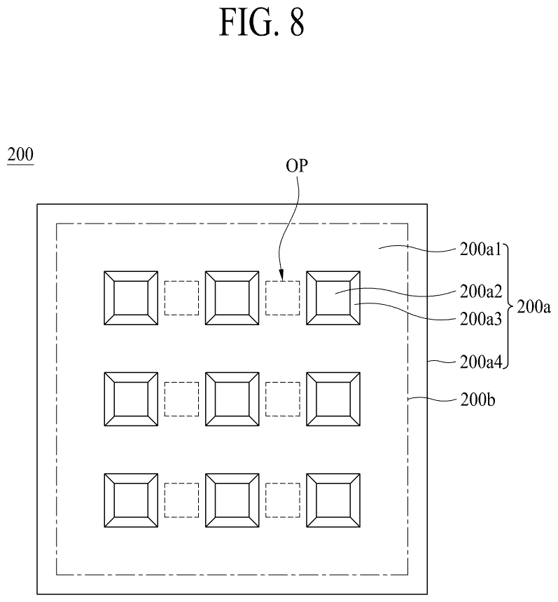

FIG. 8 is a plan view schematically illustrating an upper electrode and a lower electrode according to another example embodiment of the present disclosure. Meanwhile, the embodiment of FIG. 8 is identical to the embodiment of FIG. 6 except for the configuration of the open part, so the following description will focus on the different configuration.

As may be seen in FIG. 8, the first electrode 200 is composed of a lower electrode 200a and an upper electrode 200b.

The lower electrode 200a is composed of a protruding part 200a1, a concave part 200a2, an inclined part 200a3, and a contact part 200a4.

According to another example embodiment of the present disclosure, the lower electrode 200a may be formed by including the open part OP. In this case, since a part of the lower electrode 200a is removed by the open part OP, as described in FIG. 7, the degree to which light introduced from the outside of the display device is reflected by the lower electrode 200a and recognized by the user's eyes may be reduced or eliminated.

As may be seen in FIG. 8, the open part OP is formed in an area where the protruding part 200a1 is formed, and the open part OP may be formed between two adjacent concave parts 200a2. However, the present disclosure is not limited thereto, and the open part OP may be disposed between four adjacent concave parts 200a2. In addition, as described in FIG. 7, the open part OP may be formed in the concave part 200a2 rather than the protruding part 200a1, and the open part OP may be formed in both the protruding part 200a1 and the concave part 200a2.

The number and area of the open parts OP may be variously changed and adjusted according to the level of a person skilled in the art depending on the degree to which external light flowing in from the outside of the display device of the present disclosure is reflected on the lower electrode 200a.

Meanwhile, according to one embodiment of the present disclosure, it is preferable that the open part OP is formed in one of the areas where the protruding part 200a1 is formed and the areas where the concave part 200a2 is formed. If it is formed to overlap both the area where the protruding part 200a1 is formed and the area where the concave part 200a2 is formed, the open part OP may overlap the area where the inclined part 200a3 is formed. In this case, it is possible to partially suppress light reflected from the inclined part 200a3 from being displayed as the first sub pixel (see SP1 of FIG. 7).

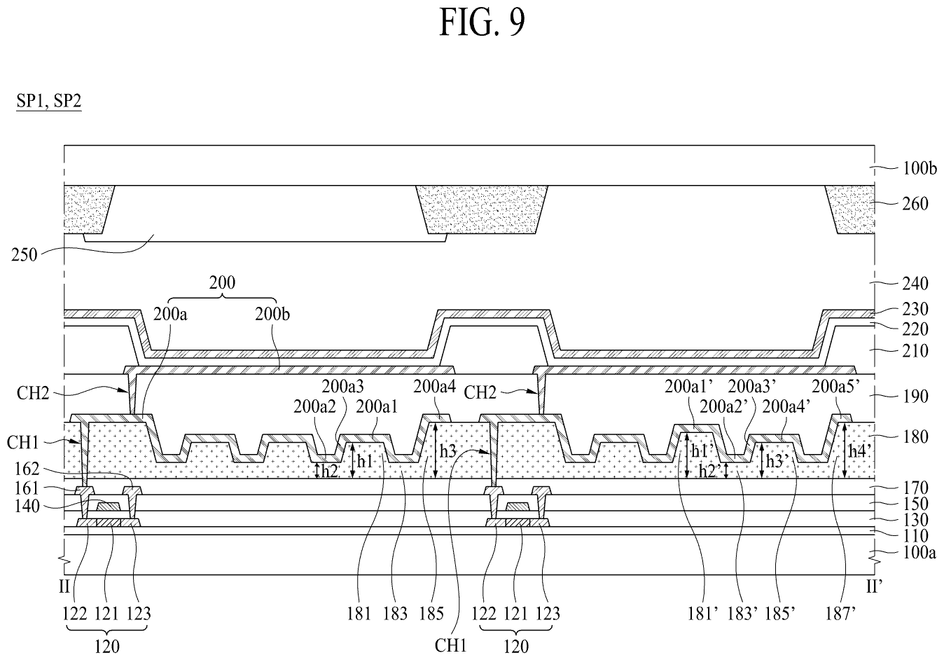

FIG. 9 is a cross-sectional view of a display device according to another example embodiment of the present disclosure. In this case, FIG. 9 corresponds to cross-section along line II-II′ in FIG. 3. Meanwhile, the embodiment of FIG. 9 is identical to the embodiment of FIG. 4 except for the second sub pixel SP2, and therefore, the following description will focus on the different configurations.

As may be seen in FIG. 9, a display device according to another example embodiment of the present disclosure includes a first sub pixel SP1 and a second sub pixel SP2. The first sub pixel SP1 may display, for example, one of red R, green G, and blue B, and the second sub pixel SP2 may display, for example, white W. Meanwhile, since the first sub pixel SP1 of FIG. 9 is the same as the first sub pixel SP1 according to the embodiment of FIG. 4, the following description will focus on the second sub pixel SP2.

According to another example embodiment of the present disclosure, the second sub pixel SP2 includes a first substrate 100a, a buffer layer 110, an active layer 120, a gate insulating layer 130, a gate electrode 140, an interlayer insulating layer 150, a source electrode 161, a drain electrode 162, a first insulating layer 170, a second insulating layer 180, a lower electrode 200a of the first electrode 200, a planarization layer 190, an upper electrode 200b of the first electrode 200, a bank 210, a light emitting layer 220, a second electrode 230, an encapsulation layer 240, a black matrix 260, and a second substrate 100b.

The second insulating layer 180 is disposed on the first insulating layer 170.

The second insulating layer 180 may be formed of a single layer or multiple layers including an inorganic insulating material and/or an organic insulating material.

According to another example embodiment of the present disclosure, the second insulating layer 180 may be formed by including portions having different heights. The second insulating layer 180 may be formed by including a first part 181′ having a first height h1′, a second part 183′ having a second height h2′, a third part 185′ having a third height h3′, and a fourth part 187′ having a fourth height h4′. In this case, the first height h1′, the second height h2′, the third height h3′, and the fourth height h4′ may be different heights from each other, for example, the fourth height h4′ may be greater than the first height h1′, the second height h2′, and the third height h3′, the first height h1′ may be greater than the second height h2′ and the third height h3′, and the third height h3′ may be greater than the second height h2′. The second insulating layer 180 may be pattern-formed by a multi-tone mask. In this case, the first part 181′, the second part 183′, the third part 185′, and the fourth part 187′ may be formed in the same process by the multi-tone mask.

The first part 181′, the second part 183′, and the third part 185′ may overlap with the light emitting area defined by the bank 210. Therefore, the first part 181′, the second part 183′, and the third part 185′ may overlap with the upper electrode 200b of the first electrode 200 that is exposed and not covered by the bank 210.

According to an example embodiment of the present disclosure, by adjusting the first height h1′, the second height h2′, and the third height h3′ of the first part 181′, the second part 183′, and the third part 185′, the distance between the lower electrode 200a and the second electrode 230 may be adjusted to become an integer multiple of a half wavelength of any one of red R, green G, and blue B light.

The first part 181′, the second part 183′, and the third part 185′ may be configured to have various heights according to red R, green G, and blue B light. For example, the first height h1′ of the first part 181′ may be adjusted so that the distance between the lower electrode 200a and the second electrode 230 becomes an integer multiple of a half wavelength of red R light, the second height h2′ of the second part 183′ may be adjusted so that the distance between the lower electrode 200a and the second electrode 230 becomes an integer multiple of a half wavelength of green G light, and the third height h3′ of the third part 185′ may be adjusted so that the distance between the lower electrode 200a and the second electrode becomes an integer multiple of a half wavelength of blue B light.

The fourth part 187′ may not overlap with the light emitting region. A first contact hole CH1 may be formed in the fourth part 187′. The upper surface of the source electrode 161 may be exposed by the first contact hole CH1.

According to another example embodiment of the present disclosure, the fourth height h4′ of the fourth part 187′ of the second sub pixel SP2 may be formed to have the same height as the third height h3 of the third part 185 of the first sub pixel SP1. By forming in this manner, the second contact hole CH2 for connecting the lower electrode 200a and the upper electrode 200b may be formed in the same process. Accordingly, since there is no need to additionally introduce a separate process for forming contact holes of different lengths, the manufacturing process and manufacturing time may be shortened.

The first electrode 200 may be disposed on the second insulating layer 180. The first electrode 200 may function as an anode. Therefore, when a signal is applied to the first electrode 200, holes moving from the first electrode 200 may flow into the light emitting layer 220. The first electrode 200 includes a lower electrode 200a and an upper electrode 200b.

The lower electrode 200a is disposed on the second insulating layer 180. The lower electrode 200a may be a reflective electrode. The lower electrode 200a may be formed of a material having high reflectivity. The lower electrode 200a may be formed of, for example, a plurality of layers in which aluminum palladium copper (APC), aluminum (Al), and indium tin oxide (ITO) are alternately laminated, a double layer structure of Ag/ITO, a double layer structure of APC/ITO, a triple layer structure of ITO/Ag/ITO, or a triple layer structure of ITO/APC/ITO, but is not limited thereto, and may be formed of a single metal layer having high reflectivity or a plurality of metal layers.

According to an example embodiment of the present disclosure, the lower electrode 200a may be formed in a curved structure. In detail, the lower electrode 200a may be disposed on the second insulating layer 180 and may be formed in the same shape as the shapes of the first part 181′, the second part 183′, the third part 185′, and the fourth part 187′ of the second insulating layer 180. Accordingly, one portion and the other portion of the lower electrode 200a may be disposed on the first part 181′ and the third part 185′ and formed in a protruding structure, and another portion of the lower electrode 200a may be disposed on the second part 183′ and formed in a concave structure. By forming in this manner, the light that has traveled from the light emitting layer 220 toward the lower electrode 200a is emitted to the outside of the second sub pixel SP2 without being trapped inside, thereby increasing the light emitting efficiency.

The lower electrode 200a may include a first protruding part 200a1′, a concave part 200a2′, a second protruding part 200a4′, an inclined part 200a3′, and a contact part 200a5′. The first protruding part 200a1′, the concave part 200a2′, the second protruding part 200a4′, the inclined part 200a3′, and the contact part 200a5′ may be disposed continuously with each other.

The first protruding part 200a1′ is disposed on the first part 181′ of the second insulating layer 180, the concave part 200a2′ is disposed on the second part 183′ of the second insulating layer 180, and the second protruding part 200a4′ is disposed on the third part 185′ of the second insulating layer 180. In this case, the first protruding part 200a1′ may be disposed at a higher position than the concave part 200a2′ and the second protruding part 200a4′, and the second protruding part 200a4′ may be disposed at a higher position than the concave part 200a2′.

According to another example embodiment of the present disclosure, by adjusting the heights of the first part 181′, the second part 183′, and the third part 185′ of the second insulating layer 180, the heights of the first protruding part 200a1′, the concave part 200a2′, and the second protruding part 200a4′ of the lower electrode 200a may be adjusted. In this case, by adjusting the first height h1′ of the first part 181′ of the second insulating layer 180, the shortest distance between the first protruding part 200a1′ and the second electrode 230 may be formed as a distance that is an integer multiple of a half wavelength of light representing one of red R, green G, and blue B, and by adjusting the second height h2′ of the second part 183′ of the second insulating layer 180, the shortest distance between the concave part 200a2′ and the second electrode 230 may be formed as a distance that is an integer multiple of a half wavelength of light representing the other of red R, green G, and blue B, and by adjusting the third height h3′ of the third part 185′ of the second insulating layer 180, the second protruding part 200a4′ and The shortest distance between the second electrodes 230 may be formed as a distance that is an integer multiple of a half wavelength of light indicating another one of red R, green G, and blue B. Accordingly, the second sub pixel SP2 indicating the white W may be disposed with a micro cavity (or micro-resonance) formed for all of the light indicating the red R, green G, and blue B.

For example, in a case where the first sub pixel SP1 displays red R, the third sub pixel (see SP3 of FIG. 3) displays green G, and the fourth sub pixel (see SP4 of FIG. 3) displays blue B, and the second sub pixel SP2 displays white W, any one of the first protruding part 200a1′, the concave part 200a2′, and the second protruding part 200a4′ of the lower electrode 200a disposed in the second sub pixel SP2, for example, the first protruding part 200a1′ may be formed with the same height as any one of the protruding part 200a1 and the concave part 200a2 of the lower electrode 200a of the first sub pixel SP1. In this case, the distance between the first protruding part 200a1′ of the second sub pixel SP2 and the second electrode 230 may be provided to be an integer multiple of a half wavelength of red R light. For example, the distance between the first protruding part 200a1′ and the second electrode 230 may be the distance between the first protruding part 200a1′ and the second electrode 230 in the height direction of the display device 10 (Z-axis). However, the present disclosure is not limited thereto, and the height of any one of the first protruding part 200a1′, the concave part 200a2′, and the second protruding part 200a4′ of the second sub pixel SP2 may be different from the heights of the protruding part 200a1 and the concave part 200a2 of the first sub pixel SP1. Although not specifically illustrated, the third sub pixel (see SP3 of FIG. 3) and the fourth sub pixel (see SP4 of FIG. 3) may include a lower electrode 200a including a protruding part and a concave part similar to the first sub pixel SP1. In this case, in the second sub pixel SP2, another one of the first protruding part 200a1′, the concave part 200a2′ and the second protruding part 200a4′, for example, the second protruding part 200a4′, may be formed with the same height as one of the protruding part and the concave part of the third sub pixel (see SP3 of FIG. 3), and in the second sub pixel SP2, another one of the first protruding part 200a1′, the concave part 200a2′ and the second protruding part 200a4′, for example, the concave part 200a2′, may be formed with the same height as one of the protruding part and the concave part of the fourth sub pixel (see SP4 of FIG. 4). In this case, the distance between the second protruding part 200a4′ of the second sub pixel SP2 and the second electrode 230 may be provided to be an integer multiple of a half wavelength of green G light, and the distance between the concave part 200a2′ of the second sub pixel SP2 and the second electrode 230 may be provided to be an integer multiple of a half wavelength of blue B light. For example, the distance between the second protruding part 200a4′ or the concave part 200a2′ and the second electrode 230 may be the distance between the second protruding part 200a4′ or the concave part 200a2′ and the second electrode 230 in the height direction of the display device 10 (Z-axis). However, the present disclosure is not limited thereto.

According to an example embodiment of the present disclosure, in the second sub pixel SP2 displaying the white color W, a micro cavity or micro-resonance is formed for all light displaying the red color R, the green color G, and the blue color B by the first protruding part 200a1′, the concave part 200a2′, and the second protruding part 200a4′, so that high light emission efficiency may be achieved without deteriorating the color purity of the white color W displayed by the second sub pixel SP2.

The inclined part 200a3′ may be disposed between the first protruding part 200a1′ and the concave part 200a2′, between the concave part 200a2′ and the second protruding part 200a4′, and between the first protruding part 200a1′ and the second protruding part 200a4′. The inclined part 200a3′ may be provided to be inclined at a predetermined angle from the upper surfaces of the first protruding part 200a1′, the second protruding part 200a4′, and the concave part 200a2′. According to one embodiment of the present disclosure, since the light emitted from the light emitting layer 220 is reflected by the inclined part 200a3′, the amount of light emitted to the outside of the second sub pixel SP2 may increase.

The contact part 200a5′ is disposed on the fourth part 187′ of the second insulating layer 180. The contact part 200a5′ may be electrically connected to the source electrode 161 through the first contact hole CH1 formed in the fourth part 187′ of the second insulating layer 180, and may be electrically connected to the upper electrode 200b through the second contact hole CH2.

The upper electrode 200b of the first electrode 200 may be disposed on the planarization layer 190. The upper electrode 200b may be electrically connected to the lower electrode 200a through the second contact hole CH2.

The upper electrode 200b may be formed as a transparent electrode. The upper electrode 200b may be formed of, for example, indium tin oxide (ITO) or indium zinc oxide (IZO).

The upper electrode 200b is disposed on the planarization layer 190, and thus may be formed in a different shape from the lower electrode 200a. In detail, unlike the lower electrode 200a which is formed in a curved shape, the upper electrode 200b may be formed to be flat. Accordingly, the upper surface of the upper electrode 200b may be formed flat without having a separate protruding part and/or concave part.

According to one embodiment of the present disclosure, since the upper surface of the upper electrode 200b is formed to be flat, light may be uniformly formed in each region of the light emitting layer 220 in contact with the upper electrode 200b. If the upper surface of the upper electrode 200b is not formed in a flat shape, the light emitting layer 220 may not be uniformly formed due to the surface of the upper electrode being curved or protruding during the process of forming the light emitting layer 220. In this case, light emitted from the light emitting layer 220 that is not uniformly formed may have a certain deviation, and thus may not form uniform light.

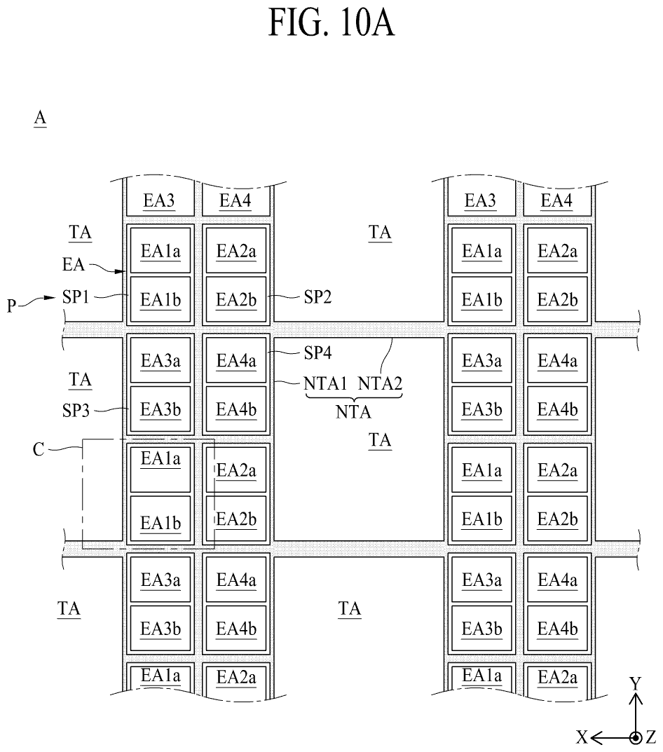

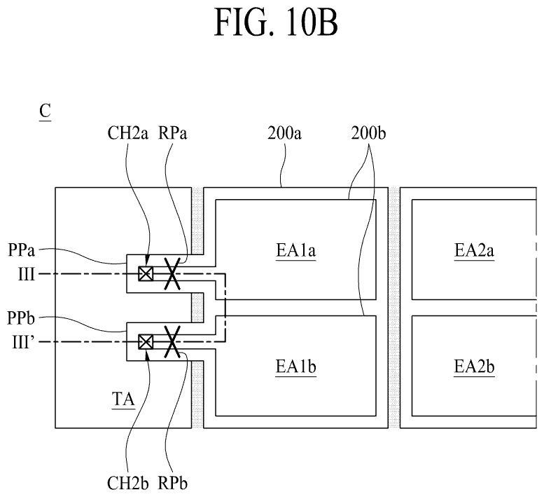

FIG. 10A is a plan view of a display device according to another example embodiment of the present disclosure. In this case, FIG. 10A is an enlarged view of area A of FIG. 2. FIG. 10B is an enlarged view of a plan view of a display device according to another example embodiment of the present disclosure. In this case, FIG. 10B is an enlarged view of area C of FIG. 10A. Meanwhile, since the embodiment of FIG. 10A is the same as the embodiment of FIG. 3 except that two light emitting areas are formed in one sub pixel, the following description will focus on different configurations.

As may be seen in FIG. 10A, a display device according to another example embodiment of the present disclosure comprises a plurality of pixel areas P, a non-transparent area NTA, and a plurality of transmissive areas TA.

According to an example embodiment of the present disclosure, the first sub pixel SP1, the second sub pixel SP2, the third sub pixel SP3, and the fourth sub pixel SP4 each include two light emitting areas. Accordingly, the first sub pixel SP1 includes a 1-1 light emitting area EA1a and a 1-2 light emitting area EA1b that display a first color among red R, green G, blue B, and white W, the second sub pixel SP2 includes a 2-1 light emitting area EA2a and a 2-2 light emitting area EA2b that display a second color among red R, green G, blue B, and white W, the third sub pixel SP3 includes a 3-1 light emitting area EA3a and a 3-2 light emitting area EA3b that display a third color among red R, green G, blue B, and white W, and the fourth sub pixel SP4 includes a 4-1 light emitting area EA4a and a 4-2 light emitting area EA4b that display a fourth color among red R, green G, blue B, and white W.

As may be seen in FIG. 10B, each of the light emitting areas according to the embodiment of the present disclosure may be formed with a repair structure to prepare for cases of pixel driving failure. For example, a repair structure may be formed by forming a protrusion on each of the upper electrode 200b and the lower electrode 200a disposed in the light emitting areas EA1a to EA4b. Accordingly, by repairing the light emitting area with a driving failure among two light emitting areas emitting one color, it is possible to implement a display device without a defect in color implementation by preserving the light emitting area that is normally driven. Below, another embodiment of the present disclosure for implementing a repair structure will be described.

As may be seen in FIG. 10B, the 1-1 light emitting area EA1a and the 1-2 light emitting area EA1b are formed by including a lower electrode 200a that is commonly formed in the 1-1 light emitting area EA1a and the 1-2 light emitting area EA1b and an upper electrode 200b that is patterned to correspond to each of the 1-1 light emitting area EA1a and the 1-2 light emitting area EA1b.

According to an example embodiment of the present disclosure, the 1-1 light emitting area EA1a includes a first protruding pattern PPa for a repair structure. The first protruding pattern PPa may be formed to extend from the 1-1 light emitting area EA1a and protrude toward one side, for example, toward an adjacent transmission portion TA, for example, toward the left.

The first protruding pattern PPa may be formed by electrically connecting a portion protruding from a lower electrode 200a disposed in the above 1-1 light emitting area EA1a and a portion protruding from an upper electrode 200b disposed in the above 1-1 light emitting area EA1a to each other through a 2-1 contact hole CH2a.

The first protruding pattern PPa includes a first repair point RPa formed between the 1-1 light emitting area EA1a and the 2-1 contact hole CH2a.

The 1-2 light emitting area EA1b comprises a second protruding pattern PPb for a repair structure. The second protruding pattern PPb may be formed to extend from the 1-2 light emitting area EA1b and protrude to one side, for example, toward an adjacent transmission portion TA, for example, to the left.

The second protruding pattern PPb may be formed by electrically connecting a portion protruding from a lower electrode 200a disposed in the above 1-2 light emitting area EA1b and a portion protruding from an upper electrode 200b disposed in the above 1-2 light emitting area EA1b to each other through a 2-2 contact hole CH2b.

The second protruding pattern PPb includes a second repair point RPb formed between the 1-2 light emitting area EA1b and the 2-2 contact hole CH2b.

For example, if a driving failure occurs in one of the 1-1 light emitting area EA1a and the 1-2 light emitting area EA1b, the display device may be driven using only normal pixels by repairing one of the first repair point RPa and the second repair point RPb. Through this, the occurrence of dark spots may be prevented or suppressed.

For example, in the case where a driving failure occurs in the 1-1 light emitting area EA1a among the 1-1 light emitting area EA1a and the 1-2 light emitting area EA1b, the first repair point RPa may be repaired so that only the 1-2 light emitting area EA1b is driven, thereby preventing or suppressing the occurrence of a dark spot.

In this case, the repair process can utilize, for example, a laser. By using the laser, the protruding part from the upper electrode 200b of the 1-1 light emitting area EA1a may be cut off, thereby disconnecting the electrical connection between the upper electrode 200b and the lower electrode 200a.

As a result, through the repair process, light generation from the 1-1 light emitting area EA1a is blocked, and the display device may be driven normally using light generated from the 1-2 light emitting area EA1b.

Meanwhile, FIG. 10B illustrates only the 1-1 light emitting area EA1a and the 1-2 light emitting area EA1b, but is not limited thereto, and may be equally applied to the 2-1 light emitting area EA2a and the 2-2 light emitting area EA2b, the 3-1 light emitting area EA3a and the 3-2 light emitting area EA3b, and the 4-1 light emitting area EA4a and the 4-2 light emitting area EA4b.

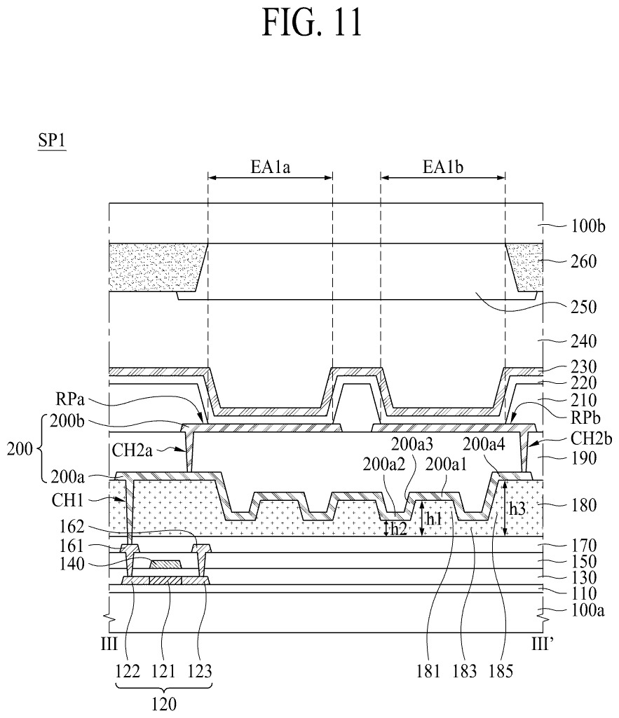

FIG. 11 is a cross-sectional view of a display device according to another example embodiment of the present disclosure. In this case, FIG. 11 corresponds to cross-section along line III-III′ in FIG. 10B. Meanwhile, the embodiment of FIG. 11 is identical to the embodiment of FIG. 4 except for the 1-1 light emitting region and the 1-2 light emitting region, so the following description will focus on the different configuration.

The display device according to another example embodiment of the present disclosure comprises a first sub pixel SP1 including a 1-1 light emitting area EA1a and a 1-2 light emitting area EA1b. In this case, the first sub pixel SP1 comprises a first substrate 100a, a buffer layer 110, an active layer 120, a gate insulating layer 130, a gate electrode 140, an interlayer insulating layer 150, a source electrode 161, a drain electrode 162, a first insulating layer 170, a second insulating layer 180, a lower electrode 200a of the first electrode 200, a planarization layer 190, an upper electrode 200b of the first electrode 200, a bank 210, a light emitting layer 220, a second electrode 230, an encapsulation layer 240, a color filter 250, a black matrix 260, and a second substrate 100b.

According to another example embodiment of the present disclosure, the lower electrode 200a may be formed to overlap the entire light emitting area of the first sub pixel SP1. In detail, the lower electrode 200a may overlap both the 1-1 light emitting area EA1a and the 1-2 light emitting area EA1b. Therefore, by forming a micro cavity for one of red R, green G, and blue B light that the first sub pixel SP1 intends to display by the protruding part 200a1 and the concave part 200a2 of the lower electrode 200a in the 1-1 light emitting area EA1a and the 1-2 light emitting area EA1b, the light emitting efficiency may be improved.

Furthermore, even when the light emitted from the light emitting layer 220 disposed in the 1-1 light emitting area EA1a and the 1-2 light emitting area EA1b is emitted at a predetermined angle with respect to the normal line of the upper surface of the light emitting layer 220, the amount of light emitted to the outside of the first sub pixel SP1 may be increased by the inclined part 200a3 of the lower electrode 200a. Accordingly, the light emitting efficiency of the first sub pixel SP1 may be improved.

The lower electrode 200a may be formed to overlap the entirety of the 1-1 light emitting area EA1a and the 1-2 light emitting area EA1b. In this case, the lower electrode 200a may receive a signal transmitted from the source electrode 161, and may apply the same signal to the upper electrode 200b of the 1-1 light emitting area EA1a and the upper electrode 200b of the 1-2 light emitting area EA1b through the 2-1 contact hole CH2a or the 2-2 contact hole CH2b.

The upper electrode 200b may be pattern-formed to correspond to the 1-1 light emitting area EA1a and the 1-2 light emitting area EA1b. Accordingly, the upper electrode 200b corresponding to the 1-1 light emitting area EA1a may be formed to be spaced apart from the upper electrode 200b corresponding to the 1-2 light emitting area EA1b, and the upper electrode 200b of the 1-1 light emitting area EA1a and the upper electrode 200b of the 1-2 light emitting area EA1b may be formed to be spaced apart from each other by the bank 210. Furthermore, a part of the lower electrode 200a commonly formed in the 1-1 light emitting area EA1a and the 1-2 light emitting area EA1b may be exposed through a spaced area between the upper electrode 200b formed in the 1-1 light emitting area EA1a and the upper electrode 200b formed in the 1-2 light emitting area EA1b.

The bank 210 disposed between the 1-1 light emitting area EA1a and the 1-2 light emitting area EA1b may overlap with the lower electrode 200a disposed in the entire area where the 1-1 light emitting area EA1a and the 1-2 light emitting area EA1b are formed. The bank 210 disposed between the 1-1 light emitting area EA1a and the 1-2 light emitting area EA1b may overlap with a part of the lower electrode 200a commonly formed in the 1-1 light emitting area EA1a and the 1-2 light emitting area EA1b.

According to an embodiment of the present disclosure, when a driving failure occurs in one of the 1-1 light emitting area EA1a and the 1-2 light emitting area EA1b, a repair point may be formed in the upper electrode 200b to remove electrical connection of the light emitting area in which the failure occurred. For example, the 1-1 light emitting area EA1a may have a first repair point RPa, and the 1-2 light emitting area EA1b may have a second repair point RPb.

In detail, the first repair point RPa of the 1-1 light emitting area EA1a may be disposed between the upper electrode 200b of the 1-1 light emitting area EA1a that is not covered by the bank 210 and the 2-1 contact hole CH2a. In detail, the second repair point RPb of the 1-2 light emitting area EA1b may be disposed between the upper electrode 200b of the 1-2 light emitting area EA1b that is not covered by the bank 210 and the 2-2 contact hole CH2b.

For example, if a driving failure occurs in one of the 1-1 light emitting area EA1a and the 1-2 light emitting area EA1b, the display device may be driven using only normal pixels by repairing one of the first repair point RPa and the second repair point RPb. Through this, the occurrence of dark spots may be prevented or suppressed.

For example, in the case where a driving failure occurs in the 1-1 light emitting area EA1a among the 1-1 light emitting area EA1a and the 1-2 light emitting area EA1b, the first repair point RPa may be repaired so that only the 1-2 light emitting area EA1b is driven, thereby preventing or suppressing the occurrence of a dark spot.

In this case, the repair process can utilize, for example, a laser. By using the laser, the protruding part from the upper electrode 200b of the 1-1 light emitting area EA1a may be cut off, thereby disconnecting the electrical connection between the upper electrode 200b and the lower electrode 200a.

As a result, through the repair process, light generation from the 1-1 light emitting area EA1a is blocked, and the display device may be driven normally using light generated from the 1-2 light emitting area EA1b.

Meanwhile, FIG. 11 illustrates only the 1-1 light emitting area EA1a and the 1-2 light emitting area EA1b, but is not limited thereto, and may be equally applied to the 2-1 light emitting area EA2a and the 2-2 light emitting area EA2b, the 3-1 light emitting area EA3a and the 3-2 light emitting area EA3b, the 4-1 light emitting area EA4a and the 4-2 light emitting area EA4b.

Although various example embodiments of the present disclosure have been described in more detail with reference to the attached drawings, the present disclosure is not necessarily limited to these embodiments, and various modifications may be made without departing from the technical idea of the present disclosure. Accordingly, the example embodiments disclosed in the present disclosure are not intended to limit the technical idea of the present disclosure but to explain it, and the scope of the technical idea of the present disclosure is not limited by these embodiments. Therefore, it should be understood that the embodiments described above are examples in all aspects and not restrictive. The protected scope of the present disclosure may be interpreted based on the claims and their equivalents, and all technical ideas within a scope equivalent thereto should be interpreted as being included in the scope of the present disclosure.

According to the various example embodiments of the present disclosure as described above, the following effects may be achieved.

According to an example embodiment of the present disclosure, the display device includes a lower electrode, which is a reflective electrode, and an upper electrode, which is a transparent electrode, formed to be spaced apart from each other with a planarization layer interposed therebetween, and by configuring the lower electrode to have an curved shape, reflection of external light is suppressed at the inclined part, and a micro cavity is formed for one of red R, green G, and blue B lights at the protruding part and concave part, thereby improving light emission efficiency.

According to example embodiments of the present disclosure, by forming an open part in an area where a protruding part of a lower electrode is formed or an area where a concave part is formed, it is possible to eliminate, minimize, or reduce external light entering from the outside of a display device from being reflected on the lower electrode and interfering with a user's vision.

According to example embodiments of the present disclosure, a lower electrode disposed in a sub pixel displaying white W includes a first protruding part positioned at a height for forming a micro cavity for red R light, a second protruding part positioned at a height for forming a micro cavity for green G light, and a concave part positioned at a height for forming a micro cavity for blue B light, thereby improving the light emission efficiency of a sub pixel displaying white W while protecting color purity from being deteriorated.

The effects of the present disclosure are not limited to the effects mentioned above, and other effects not mentioned will be clearly understood by those skilled in the art from the description above.

What is claimed is:

1. A display device, comprising:
a substrate;
a first electrode disposed on the substrate and including an upper electrode and a lower electrode;
a light emitting layer on the first electrode; and
a second electrode on the light emitting layer,
wherein the lower electrode includes a protruding part and a concave part disposed at a different height from the protruding part, and
wherein the protruding part is spaced apart from the upper electrode.

2. The display device of claim 1,
wherein the lower electrode further includes an inclined part disposed between the protruding part and the concave part.

3. The display device of claim 1,
wherein the upper electrode is a transparent electrode, and the lower electrode is a reflective electrode.

4. The display device of claim 1,
wherein the upper electrode has a shape different from a shape of the lower electrode.

5. The display device of claim 4,
wherein an upper surface of the upper electrode is planar.

6. The display device of claim 1,
wherein a distance between the protruding part of the lower electrode and the second electrode is a distance at which a micro cavity forms for one of red, green, and blue lights.

7. The display device of claim 6,
wherein a distance between the concave part of the lower electrode and the second electrode is a distance at which the micro cavity forms for one of red, green, and blue lights.

8. The display device of claim 6,
wherein a distance between the concave part of the lower electrode and the second electrode is a distance at which the micro cavity forms for another one of red, green, and blue lights.

9. The display device of claim 8,
wherein the lower electrode further includes a second protruding part disposed at a height different from heights of the protruding part and the concave part, and
wherein a distance between the second protruding part and the light emitting layer is a distance at which the micro cavity forms for yet another one of red, green, and blue lights.

10. The display device of claim 1, further comprising:
a plurality of open parts disposed in one of the protruding part and the concave part.

11. The display device of claim 10, further comprising:
an insulating layer disposed below the lower electrode and having the same shape as the lower electrode,
wherein the insulating layer includes a first part having a first height and a second part having a second height, and
wherein the plurality of open parts expose a portion of an upper surface of either the first part or the second part.

12. The display device of claim 1, further comprising:
a planarization layer disposed between the upper electrode and the lower electrode to planarize a lower surface of the upper electrode,
wherein the planarization layer includes a contact hole for electrically connecting the upper electrode and the lower electrode.

13. A display device, comprising:
a substrate including a first sub pixel,
a first electrode including a first upper electrode and a first lower electrode;
a first light emitting layer on the first electrode; and
a second electrode on the first light emitting layer,
wherein the first sub pixel is disposed on the substrate,
wherein the first lower electrode includes a first protruding part and a first concave part disposed at a different height from the first protruding part, and
wherein the first protruding part is spaced apart from the first upper electrode.

14. The display device of claim 13,
wherein the first sub pixel includes a 1-1 sub pixel and a 1-2 sub pixel displaying the same color,
wherein the first lower electrode disposed in the 1-1 sub pixel and the first lower electrode disposed in the 1-2 sub pixel are continuously disposed, and
wherein the first upper electrode disposed in the 1-1 sub pixel and the first upper electrode disposed in the 1-2 sub pixel are spaced apart from each other.

15. The display device of claim 14,
wherein an upper surface of the first lower electrode is exposed by a spaced region between the first upper electrode of the 1-1 sub pixel and the first upper electrode of the 1-2 sub pixel.

16. The display device of claim 13, further comprising:
a second sub pixel displaying a color different from that of the first sub pixel,
wherein the second sub pixel includes:
a third electrode disposed on the substrate and including a second upper electrode and a second lower electrode;
a second light emitting layer on the third electrode; and
a fourth electrode on the second light emitting layer,
wherein the second lower electrode includes a second protruding part and a second concave part disposed at a different height from the second protruding part, and
wherein the second protruding part is spaced apart from the second upper electrode.

17. The display device of claim 16,
wherein a distance between the second light emitting layer and the second protruding part is equal to a distance between the first light emitting layer and either the first protruding part or the first concave part.

18. The display device of claim 16,
wherein a distance between the first protruding part of the first lower electrode disposed in the first sub pixel and the first light emitting layer and a distance between the first concave part and the first light emitting layer are distances at which a micro cavity forms for one of red, green, and blue lights,
wherein a distance between the second protruding part of the second lower electrode disposed in the second sub pixel and the second light emitting layer is a distance at which a micro cavity forms for one of red, green, and blue lights, and
wherein a distance between the second concave part of the second lower electrode disposed in the second sub pixel and the second light emitting layer is a distance at which a micro cavity forms for another one of red, green, and blue lights.

19. The display device of claim 18,
wherein the second sub pixel further includes a third protruding part disposed at a height different from heights of the second protruding part and the second concave part, and
wherein a distance between the third protruding part and the second light emitting layer is a distance at which a micro cavity forms for yet another one of red, green, and blue lights.

20. The display device of claim 16,
wherein the first sub pixel displays one of red, green, and blue colors, and the second sub pixel displays white color.

21. The display device of claim 16,
wherein a shortest distance between an upper surface of the first lower electrode and a lower surface of the first upper electrode is equal to a shortest distance between an upper surface of the second lower electrode and the lower surface of the second upper electrode.

22. A display device, comprising:
a substrate;
an upper electrode and a lower electrode disposed on the substrate; and
an insulating layer disposed below the lower electrode,
wherein the lower electrode comprises:
a protruding part and a concave part disposed at a height different from the protruding part; and
an open part disposed in the protruding part and/or the concave part and exposing a portion of an upper surface of the insulating layer.

23. The display device according to claim 22, further comprising an inclined part disposed between the protruding part and the concave part.

24. The display device according to claim 22, wherein the open part is formed by removing a part of the lower electrode.
